(19) United States
(12) Patent Application Publication
(10) Pub. No.: US 2025/0372579 A1
(43) Pub. Date: Dec. 4, 2025

(54) SEMICONDUCTOR PACKAGE INCLUDING MULTI-PART CONNECTION

(71) Applicant: SAMSUNG ELECTRONICS CO., LTD., SUWON-SI (KR)

(72) Inventor: Junghoon KANG, Suwon-si (KR)

(21) Appl. No.: 18/968,846

(22) Filed: Dec. 4, 2024

(30) Foreign Application Priority Data
May 28, 2024 (KR) 10-2024-0069295

(51) Int. Cl. H01L 25/065; H01L 21/48; H01L 21/56; H01L 23/00; H01L 23/498

(52) U.S. Cl. CPC H01L 25/0657; H01L 23/49838; H01L 23/49866; H01L 24/16; H01L 21/4853; H01L 21/565; H01L 24/32; H01L 24/73; H01L 2224/1403; H01L 2224/16227; H01L 2224/32145; H01L 2224/73203; H01L 2224/73253; H01L 2225/06517; H01L 2225/06548; H01L 2225/06562; H01L 2924/1815

(57) ABSTRACT

A semiconductor package includes a package substrate, a first chip arranged to be spaced apart from the package substrate in a first direction perpendicular to the package substrate, a second chip disposed closer to the package substrate than the first chip and spaced apart from the package substrate, a first pillar extending along the first direction from the first chip toward the package substrate, a first via disposed between the first pillar and the package substrate, a second pillar extending along the first direction from the second chip toward the package substrate, and a second via disposed between the second pillar and the package substrate, and the first via and the second via have a width that decreases with distance away from the package substrate.

### CROSS-REFERENCE TO RELATED APPLICATION(S)

This application claims priority under 35 U.S.C. § 119 to Korean Patent Application No. 10-2024-0069295, filed on May 28, 2024, in the Korean Intellectual Property Office, the disclosure of which is herein incorporated by reference.

### BACKGROUND

### 1. Technical Field

Example embodiments relate to a semiconductor package, and more particularly to a semiconductor package including a multi-part connection.

### 2. Discussion of Related Art

The electronics industry continues to develop to meet demands for high functionality, high speed, and small electronic components. For example, a method of stacking and mounting multiple semiconductor chips on a single package wiring structure or stacking packages on top of a package can be used to improve packaging and performance of electronic components. In particular, a package-in-package (PIP) type semiconductor package or a package-on-package (POP) type semiconductor package may be used.

### SUMMARY

An aspect of the present disclosure provides a highly integrated semiconductor package.

Another aspect of the present disclosure also provides a semiconductor package with improved structural stability.

Aspects of the present disclosure are not limited to aspects described herein, and other aspects may be inferred from the following disclosure by those skilled in the art.

According to an aspect, there is provided a semiconductor package including a package substrate, a first chip arranged to be spaced apart from the package substrate in a first direction perpendicular to the package substrate, a second chip disposed closer to the package substrate than the first chip and spaced apart from the package substrate, a first pillar extending along the first direction from the first chip toward the package substrate, a first via disposed between the first pillar and the package substrate, a second pillar extending along the first direction from the second chip toward the package substrate, and a second via disposed between the second pillar and the package substrate, and the first via and the second via have a width that decreases with distance away from the package substrate.

According to another aspect, there is provided a semiconductor package including a package substrate, a first chip arranged to be spaced apart from the package substrate in a first direction perpendicular to the package substrate, a second chip disposed closer to the package substrate than the first chip, a third chip disposed closest to the package substrate in the first direction and spaced apart from the package substrate, a first pillar extending along the first direction from the first chip toward the package substrate, a first via disposed between the first pillar and the package substrate, a second pillar extending along the first direction from the second chip toward the package substrate, a second via disposed between the second pillar and the package substrate, a third pillar extending along the first direction from the third chip to the package substrate, and the first via has a surface that is rougher than a surface of the first pillar and the third pillar has a surface that is less rough than a surface of the first via.

According to another aspect, there is provided a semiconductor package including a package substrate, a first chip arranged to be spaced apart from the package substrate in a first direction perpendicular to the package substrate, a second chip disposed closer to the package substrate than the first chip, a third chip disposed closest to the package substrate in the first direction, a first pillar extending along the first direction from the first chip toward the package substrate, a first via disposed between the first pillar and the package substrate, a second pillar extending along the first direction from the second chip toward the package substrate, a second via disposed between the second pillar and the package substrate, and a third pillar extending along the first direction from the third chip to the package substrate, the first via has a surface that is rougher than a surface of the first pillar and the second via has a surface that is rougher than a surface of the second pillar.

Additional aspects of example embodiments will be set forth in part in the description which follows and, in part, will be apparent from the description, or may be learned by practice of the disclosure.

According to example embodiments, it is possible for a semiconductor package to be highly integrated.

According to example embodiments, it is possible to improve the structural stability of a semiconductor package.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a diagram for explaining a semiconductor package according to an example embodiment;

FIG. 2 is an enlarged view illustrating a portion P of FIG. 1;

FIG. 3 is a diagram for explaining a semiconductor package according to an example embodiment;

FIG. 4 is a diagram for explaining a semiconductor package according to an example embodiment;

FIG. 5 is a diagram for explaining a semiconductor package according to an example embodiment;

FIGS. 6 to 12 are diagrams illustrating intermediate processes for explaining a method for manufacturing a semiconductor package according to an example embodiment; and

FIGS. 13 to 16 are diagrams illustrating intermediate processes for explaining a method of manufacturing a semiconductor package according to an example embodiment.

### DETAILED DESCRIPTION

Hereinafter, embodiments of the present disclosure are described clearly and in detail such that those skilled in the art may easily reproduce the present disclosure. Inventive concepts may be implemented in various modifications and have various forms. It is to be understood, however, that the inventive concepts are not intended to be limited to the particular forms disclosed, but on the contrary, is intended to cover all modifications, equivalents, and alternatives falling within the spirit and scope of the inventive concepts.

Terms or words used in the specification and claims should not be construed as limited to their common or dictionary meanings. Further, the terms or words should be interpreted with meaning and concept consistent with the technical idea of the present disclosure based on the principle that the inventor may appropriately define the concept of terms in order to explain his or her invention. Example embodiments described in this specification and the configurations shown in the drawings do not necessarily represent the entire technical idea of the present disclosure.

In the following description, singular expressions may include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. The terms “have,” “may have,” “include,” and “may include” as used herein may indicate the presence of corresponding features (for example, elements such as numerical values, functions, operations, or parts), and may not preclude the presence of additional features.

Further, in the following description, directional expressions such as an upper side, top, a lower side, bottom, a side, front and a back side may be expressed based on the direction shown in the drawing. If the direction of the object changes, directional expressions may be expressed differently. The shapes and sizes of elements in the drawings may be exaggerated for clearer explanation.

Hereinafter, example embodiments of the present invention will be described with reference to the attached drawings.

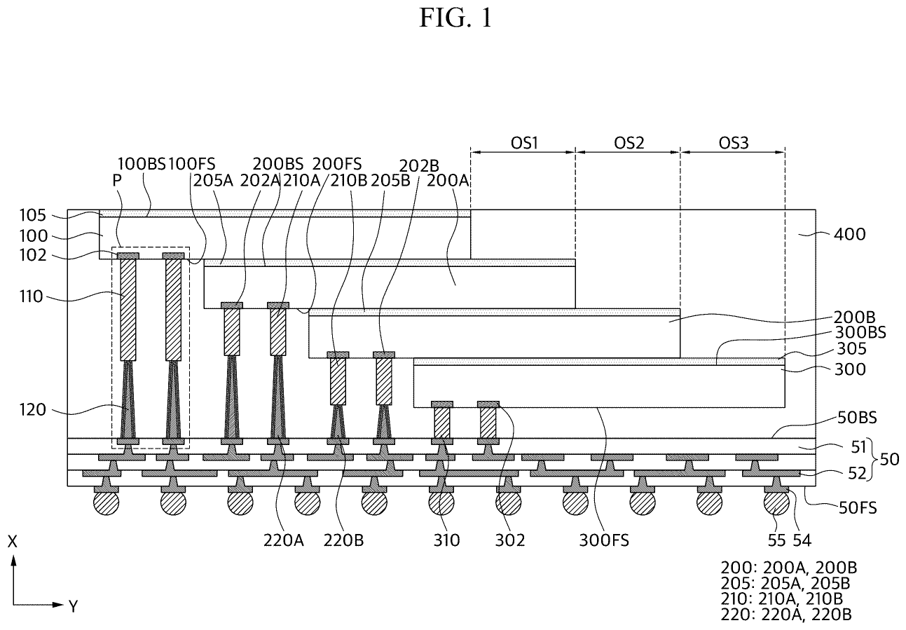

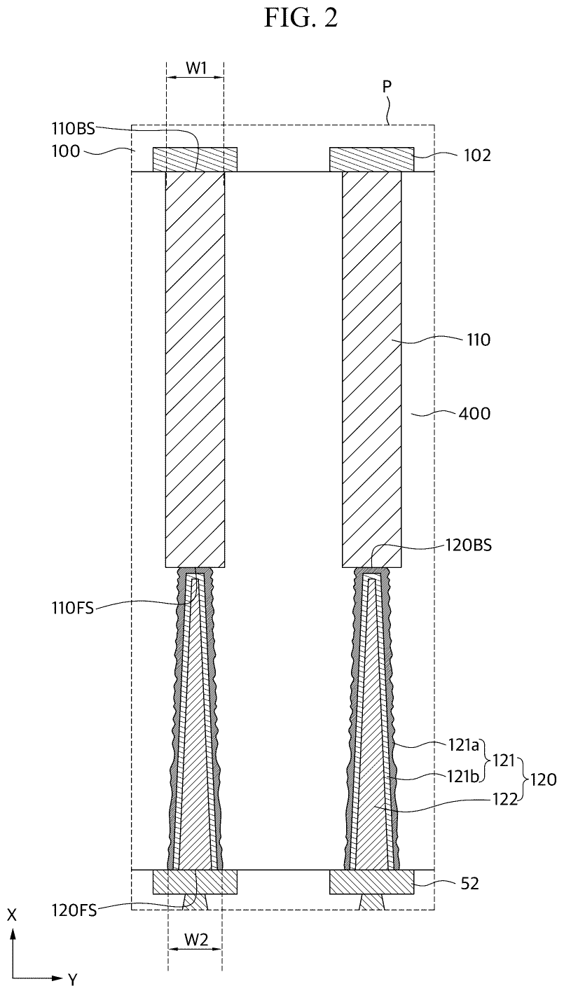

FIG. 1 is a diagram for explaining a semiconductor package according to an example embodiment. FIG. 2 is an enlarged view illustrating a portion P of FIG. 1. More particularly, FIG. 2 depicts a multi-part connection electrically connecting a first chip 100 to a substrate wiring structure 52, and including the first pillar 110 and the first via 120 stacked on the first pillar 110. FIG. 1 and FIG. 2 may be described in the context of a first direction X and a second direction Y, intersecting the first direction X. The first direction X may be vertical direction and the second direction Y may be a horizontal direction.

Referring to FIG. 1 and FIG. 2, the semiconductor package may include a package substrate 50, a first chip 100, a second chip 200, a third chip 300, a first pillar 110, a second pillar 210, a third pillar 310, a first via 120, a second via 220 and a molding layer 400.

According to some example embodiments, the second chip 200 may be provided in the singular, and the semiconductor package may include second chip 200A, and may omit second chip 200B illustrated in FIG. 1. According to some example embodiments, the second chip 200 may be provided in the plurality, and the semiconductor package may include at least the second chip 200A and the second chip 200B. Descriptions of the second chip 200 may be applied to both the second chip 200A and the second chip 200B. In an implementation of the semiconductor package including the second chip 200A and the second chip 200B, any difference thereof may be explicitly described.

According to some example embodiments, the package substrate 50 may be disposed under the first chip 100, the second chip 200 and the third chip 300. The package substrate 50 may be electrically connected to the first chip 100, the second chip 200 and the third chip 300. The first chip 100, the second chip 200 and the third chip 300 may exchange electrical signals with external devices through the package substrate 50.

According to some example embodiments, the package substrate 50 may be a wiring structure for a package. For example, the package substrate 50 may be a printed circuit board (PCB), a ceramic substrate, or an interposer. Alternatively, the package substrate 50 may be a wiring structure for a wafer level package (WLP), which may be manufactured at the wafer level. The package substrate 50 may be a semiconductor chip including a semiconductor device. The package substrate 50 may be a support substrate for a semiconductor package.

According to some example embodiments, the package substrate 50 may be a glass substrate, a ceramic substrate or a plastic substrate, but the package substrate 50 is not limited thereto. For example, the package substrate 50 may include a resin impregnated in a core material such as glass fiber, glass cloth, or glass fabric together with an inorganic filler. For example, prepreg, an insulating film such as that used in connection with the trademark AJINOMOTO BUILD-UP FILM® (ABF), FR-4, or bismaleimide triazine (BT) may be used.

According to some example embodiments, the package substrate 50 may include bulk silicon or silicon-on-insulator (SOI). In another example embodiment, the package substrate 50 may be a silicon substrate. In another example embodiment, the package substrate 50 may include silicon germanium, silicon germanium on insulator (SGOI), indium antimonide, lead telluride, indium arsenide, indium phosphide, gallium arsenide or gallium antimonide. However, the present disclosure is not limited thereto.

According to some example embodiments, the package substrate 50 may include a challenge region, for example, a doped well or a doped structure. The package substrate 50 may have various device isolation structures, such as a shallow trench isolation (STI) structure.

According to some example embodiments, the package substrate 50 may include multiple layers. For example, the package substrate 50 may include a substrate body part 51 and a substrate wiring structure 52.

According to some example embodiments, when the package substrate 50 is a PCB, the substrate body part 51 may be made of at least one material selected from phenol resin, epoxy resin, or polyimide. The package substrate 50 may include at least one material selected from tetrafunctional epoxy, polyphenylene ether, epoxy/polyphenylene oxide, BT, thermount, cyanate ester, or liquid crystal polymer.

According to some example embodiments, the substrate body part 51 may include a photoimageable dielectric. In an example embodiment, the substrate body part 51 may include a photosensitive polymer. The photosensitive polymer may be formed of at least one of, for example, a photosensitive polyimide, a polybenzoxazole, a phenol-based polymer, or a benzocyclobutene-based polymer. In another example embodiment, the substrate body part 51 may be formed of a silicon oxide film, a silicon nitride film, or a silicon oxynitride film.

The surface of the substrate body part 51 may be covered with solder resist. For example, a passivation film may be located on the surface of the substrate body part 51. The passivation film located on the surface of the substrate body part 51 may protect the substrate wiring structure 52 and other structures from external impact or moisture. The passivation film may include a solder resist. However, the present disclosure is not limited thereto.

According to some example embodiments, the substrate wiring structure 52 may be arranged within the substrate body part 51. The substrate body part 51 may include multiple layers. The substrate wiring structure 52 may include wiring patterns and wiring vias connecting each wiring pattern. For example, the substrate wiring structure 52 may be a multilayer structure in which two or more wiring patterns or two or more wiring vias are alternately stacked. For example, the two or more wiring patterns of the substrate wiring structure 52 may be disposed in two or more layer of the substrate body part 51. For example, the wiring pattern may extend in the second direction Y. The wiring via may connect wiring patterns spaced apart in the first direction X.

According to some example embodiments, the substrate wiring structure 52 may include a conductive material. For example, the substrate wiring structure 52 may include copper (Cu), aluminum (Al), silver (Ag), tin (Sn), gold (Au), nickel (Ni), lead (Pb), or titanium (Ti), or alloys thereof. However, the substrate wiring structure 52 is not limited thereto.

According to some example embodiments, an external connection terminal 55 may be located on a front side surface 50FS of the package substrate. The external connection terminal 55 may be disposed on an external connection pad 54. The external connection terminal 55 may contact the external connection pad 54. The external connection terminal 55 may include a solder ball or a solder bump. The external connection terminal 55 may be, for example, spherical or elliptical in shape. However, the external connection terminal 55 is not limited thereto. The number, spacing, arrangement, and shape of the external connection terminal 55 are not limited, and may vary depending on the design. The external connection terminal 55 may include, for example, tin (Sn), indium (In), bismuth (Bi), antimony (Sb), copper (Cu), silver (Ag), zinc (Zn), or lead (Pb), or combinations thereof. However, the external connection terminal 55 is not limited thereto.

According to some example embodiments, the external connection terminal 55 may electrically connect the substrate wiring structure 52 to an external device. Accordingly, the external connection terminal 55 may provide an electrical signal to the substrate wiring structure 52, or may provide an electrical signal from the substrate wiring structure 52 to an external device.

For example, the external connection terminal 55 may provide electrical signals for the first chip 100, the second chip 200, or the third chip 300. The external connection terminal 55 may receive a signal that is input to the first chip 100, the second chip 200 or the third chip 300. The external connection terminal 55 may receive a signal that is output from the first chip 100, the second chip 200 or the third chip 300.

According to some example embodiments, the first chip 100, the second chip 200 and the third chip 300 may be disposed on the package substrate 50. For example, the first chip 100, the second chip 200 and the third chip 300 may be stacked on the package substrate 50.

According to some example embodiments, each of the first chip 100, the second chip 200 and the third chip 300 may include an integrated circuit (IC). The first chip 100, the second chip 200, and the third chip 300 may include an active surface on which the IC may be formed and an inactive surface disposed on the opposite side of the active surface. The active surface may be referred to as the front side surface. The inactive surface may be referred to as the back side surface. For example, the front side surface may refer to the surface facing the package substrate 50. The inactive surface may refer to a surface positioned opposite the front side surface.

According to some example embodiments, the first chip 100, the second chip 200 and the third chip 300 may be memory semiconductor chips. The memory semiconductor chip may be a volatile memory, such as, for example, dynamic random access memory (DRAM) or static random access memory (SRAM). Alternatively, memory semiconductor chips may be non-volatile memory, such as flash memory, phase-change random access memory (PRAM), magnetic random access memory (MRAM), ferroelectric random access memory (FeRAM), or resistive random access memory (RRAM). However, the present disclosure is not limited thereto.

For example, at least some of the first chip 100, the second chip 200, or the third chip 300 may be logic semiconductor chips. The logic semiconductor chip may include, for example, a central processing unit (CPU), a graphic processing unit (GPU), field-programmable gate array (FPGA), digital signal processor, cryptographic processor, microprocessor, or an application processor (AP) such as a microcontroller or an application-specific IC (ASIC).

According to some example embodiments, the first chip 100 may be disposed on the second chip 200 (e.g., second chip 200A), and the second chip 200 may be disposed on the third chip 300 or another second chip (e.g., second chip 200B). The first chip 100 may be arranged to be spaced furthest from the package substrate 50 in the first direction X perpendicular to the package substrate 50. The first chip 100 may be disposed further away from the package substrate 50 than the second chip 200 and the third chip 300.

According to some example embodiments, the first chip 100 may include a first connection pad 102 disposed on a first chip front side surface 100FS. The first chip front side surface 100FS may be the active side of the first chip 100. The first connection pad 102 may be in contact with the first pillar 110. The first connection pad 102 may be electrically connected to the first pillar 110. The first connection pad 102 may be disposed on a first pillar back side surface 110BS of the first pillar 110 (see FIG. 2).

According to some example embodiments, the second chip 200 may be disposed closer to the package substrate 50 than the first chip 100. The second chip 200 may be disposed between the first chip 100 and the third chip 300 in the first direction X. A plurality of second chips 200 (e.g., 200: 200A, 200B) may be disposed in the semiconductor package. FIG. 1 illustrates that the two second chips 200: 200A, 200B are arranged in a stack, but the present disclosure is not limited thereto. For example, three or more second chips 200 may be disposed between the first chips 100 and the third chips 300.

According to some example embodiments, the second chip 200 may include a second connection pad 202: 202A, 202B disposed on a second chip front side surface 200FS. The second chip front side surface 200FS may be the active side of the second chip 200. The second connection pad 202: 202A, 202B may be in contact with the second pillar 210: 210A, 210B. For example, the second connection pad 202A may be in contact with the second pillar 210A, and the second connection pad 202B may be in contact with the second pillar 210B. The second connection pad 202: 202A, 202B may be electrically connected to the second pillar 210: 210A, 210B. The second connection pad 202: 202A, 202B may be disposed on the first side of the second pillar 210: 210A, 210B. The first side of the second pillar 210: 210A, 210B may be the side facing the second chip 200: 200A, 200B.

According to some example embodiments, the second chip 200A may overlap the first pillar 110 or the first via 120 connected to the first chip 100 in the second direction Y. In an example embodiment, among the plurality of second chips 200: 200A, 200B, the second chip 200A disposed adjacent to the first chip 100 may overlap the first pillar 110 in the second direction Y. In another example embodiment, among the plurality of second chips 200: 200A, 200B, the second chip 200B disposed adjacent to the third chip 300 may overlap the first via 120 in the second direction Y. In another example embodiment, the second chip 200A may overlap at least a portion of the first pillar 110 and at least a portion of the first via 120 in the second direction Y.

According to some example embodiments, the third chip 300 may be disposed closest to the package substrate 50 in the first direction X among the first chip 100, the second chip 200 and the third chip 300.

According to some example embodiments, the third chip 300 may include a third connection pad 302 disposed on a third chip front side surface 300FS. The third chip front side surface 300FS may be the active side of the third chip 300. The third connection pad 302 may be electrically connected to the third pillar 310. The third connection pad 302 may be disposed on the first side of the third pillar 310. The first side of the third pillar 310 may be the side facing the third chip 300.

According to some example embodiments, the first chip 100 may include a first adhesive layer 105. The first adhesive layer 105 may be disposed on a first chip back side surface 100BS. The first chip back side surface 100BS may refer to the side opposite to the first chip front side surface 100FS. The second chip 200: 200A, 200B may include a second adhesive layer 205. The second adhesive layer 205: 205A, 205B may be disposed on a second chip back side surface 200BS. The second chip back side surface 200BS may refer to the side opposite to the second chip front side surface 200FS. The third chip 300 may include a third adhesive layer 305. The third adhesive layer 305 may be disposed on a third chip back side surface 300BS. The third chip back side surface 300BS may refer to the side opposite to the third chip front side surface 300FS. The first adhesive layer 105, the second adhesive layer 205: 205A, 205B, and the third adhesive layer 305 may fix the first chip 100, the second chip 200: 200A, 200B, and the third chip 300 to each other.

According to some example embodiments, the first adhesive layer 105, the second adhesive layer 205: 205A, 205B and the third adhesive layer 305 may include a non-conductive film (NCF), a non-conductive paste (NCP), insulating polymer, and/or epoxy resin. However, the present disclosure is not limited thereto. For example, the first adhesive layer 105, the second adhesive layer 205: 205A, 205B and the third adhesive layer 305 may be tapes that may secure the first chip 100, the second chip 200: 200A, 200B and the third chip 300 to each other. The first adhesive layer 105, the second adhesive layer 205: 205A, 205B and the third adhesive layer 305 may be, for example, tapes containing an epoxy component.

According to some example embodiments, the first chip 100, the second chip 200: 200A, 200B and the third chip 300 may be sequentially arranged offset in the second direction Y. Here, the chips being offset may indicate that the plurality of chips are arranged to be staggered by a certain distance so that the chips do not completely overlap in the first direction X. For example, the second chip 200A may be arranged offset in the second direction Y with the first chip 100 and the first offset distance OS1. The second chip 200A may be offset from the first chip 100, exposing the first connection pad 102 of the first chip 100.

According to some example embodiments, the plurality of second chips 200: 200A, 200B may be arranged offset. One second chip 200 (e.g., second chip 200A) may be arranged to be offset from another second chip 200 (e.g., second chip 200B) in the second direction Y at a second offset distance OS2. More particularly, the second chip 200A may be arranged to be offset from the second chip 200B in the second direction Y at a second offset distance OS2. Further, the second chip 200A may be offset from the second chip 200B, exposing the second connection pad 202A of the second chip 200A. The third chip 300 may be arranged offset in the second direction Y with the second chip 200B and the third offset distance OS3. The third chip 300 may be offset from the second chip 200B, exposing the second connection pad 202B of the second chip 200B. The first offset distance OS1, the second offset distance OS2, and the third offset distance OS3 may be the same. However, the present disclosure is not limited thereto. For example, the first offset distance OS1, the second offset distance OS2, and the third offset distance OS3 may be different from each other.

According to some example embodiments, the first pillar 110 may be disposed on the first chip 100. Specifically, the first pillar 110 may be disposed on the first chip front side surface 100FS. The first pillar 110 may extend along the first direction X from the first chip 100 toward the package substrate 50. The first pillar 110 may penetrate the molding layer 400. The first pillar 110 may be surrounded by the molding layer 400.

According to some example embodiments, the first pillar 110 may be disposed on the first connection pad 102. Specifically, the first pillar 110 may be disposed on the front side surface of the first connection pad 102. The front side surface of the first connection pad 102 may refer to the surface facing the package substrate 50. The first pillar 110 may be disposed between the first connection pad 102 and the first via 120. The first pillar 110 may electrically connect the first connection pad 102 and the first via 120. For example, the first chip 100 may be electrically connected to the package substrate 50 by a multi-part connection including the first pillar 110 and the first via 120 stacked on the first pillar 110.

For example, the first pillar 110 may have a first pillar front side surface 110FS and the first pillar back side surface 110BS. The first pillar front side surface 110FS may be the side facing the package substrate 50. The first pillar back side surface 110BS may be the surface facing the first chip 100. The first pillar back side surface 110BS may be a surface disposed on the opposite side of the first pillar front side surface 110FS in the first direction X.

According to some example embodiments, in the first direction X, the length of the first pillar 110 may be longer than the lengths of the second pillar 210: 210A, 210B and the third pillar 310. In the second direction Y, the width of the first pillar 110 may be constant. In the second direction Y, each of the width of the first pillar front side surface 110FS and the width of the first pillar back side surface 110BS may be the first width W1.

According to some example embodiments, the aspect ratio of the first pillar 110 may be about 4 or less. The aspect ratio of the first pillar 110 may indicate the ratio of the height of the first pillar 110 in the first direction X to the width of the first pillar 110 in the second direction Y. For example, the aspect ratio of the first pillar 110 may be about 2 or more and about 3 or less.

According to some example embodiments, the second pillar 210: 210A, 210B may be disposed on the second chip 200: 200A, 200B. Specifically, the second pillar 210: 210A, 210B may be disposed on the second chip front side surface 200FS. The second pillar 210: 210A, 210B may extend along the first direction X from the second chip 200 toward the package substrate 50. The second pillar 210 may penetrate the molding layer 400. The second pillar 210: 210A, 210B may be surrounded by the molding layer 400. In the first direction X, the length of the second pillar 210: 210A, 210B may be shorter than the length of the first pillar 110. In the first direction X, the length of the second pillar 210: 210A, 210B may be longer than the length of the third pillar 310. However, the present disclosure is not limited thereto. For example, in the first direction X, the length of the second pillar 210: 210A, 210B may be the same as the length of the third pillar 310.

According to some example embodiments, the second pillar 210: 210A, 210B may be disposed on the second connection pad 202: 202A, 202B. For example, the second pillar 210A may be disposed on the second connection pad 202A, and the second pillar 210B may be disposed on the second connection pad 202B. Specifically, the second pillar 210: 210A, 210B may be disposed on the front side surface of the second connection pad 202. The front side surface of the second connection pad 202: 202A, 202B may refer to the side facing the package substrate 50. The second pillar 210: 210A, 210B may be disposed between the second connection pad 202: 202A, 202B and the second via 220: 220A, 220B. The second pillar 210: 210A, 210B may electrically connect the second connection pad 202: 202A, 202B and the second via 220: 220A, 220B.

According to some example embodiments, the second pillars 210 arranged on the plurality of second chips 200: 200A, 200B may have the same length in the first direction X. For example, among the plurality of second chips 200: 200A, 200B, the length of the second pillar 210: 210A, 210B disposed on the single second chip 200: 200A, 200B disposed closer to the first chip 100 than the third chip 300 and the length of the second pillar 210: 210A, 210B disposed on another second chip 200: 200A, 200B disposed closer to the third chip 300 than the first chip 100 may be the same in the first direction X. The width of the second pillar 210: 210A, 210B in the second direction Y may be constant.

According to some example embodiments, the aspect ratio of the second pillar 210: 210A, 210B may be 3 or less. The aspect ratio of the second pillar 210: 210A, 210B may indicate the ratio of the height of the second pillar 210: 210A, 210B in the first direction X to the width of the second pillar 210: 210A, 210B in the second direction Y. For example, the aspect ratio of the second pillar 210: 210A, 210B may be 1 or more and 2 or less.

According to some example embodiments, the third pillar 310 may be disposed on the third chip 300. Specifically, the third pillar 310 may be disposed on the third chip front side surface 300FS. The third pillar 310 may extend along the first direction X from the third chip 300 to the package substrate 50. The third pillar 310 may directly contact the package substrate 50. The third pillar 310 may penetrate the molding layer 400. The third pillar 310 may be surrounded by the molding layer 400.

According to some example embodiments, the third pillar 310 may be disposed on the third connection pad 302. Specifically, the third pillar 310 may be disposed on the front side surface of the third connection pad 302. The front side surface of the third connection pad 302 may refer to the side facing the package substrate 50. The third pillar 310 may be disposed between the second connection pad 202 and the substrate wiring structure 52. The third pillar 310 may electrically connect the third connection pad 302 and the substrate wiring structure 52.

According to some example embodiments, in the first direction X, the length of the third pillar 310 may be shorter than the lengths of the first pillar 110 and the second pillar 210: 210A, 210B. However, the present disclosure is not limited thereto. For example, the length of the third pillar 310 may be equal to or greater than the length of the second pillar 210. In the second direction Y, the width of the third pillar 310 may be constant.

According to some example embodiments, the surface of the third pillar 310 may be less rough than the surface of the first via 120. The third pillar 310 may have a flatter surface than the first via 120.

According to some example embodiments, the material included in the first pillar 110 may have the same composition ratio as the material included in the second pillar 210: 210A, 210B and the third pillar 310. For example, each of the first pillar 110, the second pillar 210: 210A, 210B and the third pillar 310 may include the same constituent material, and the composition ratio of each component contained in the first pillar 110, the second pillar 210: 210A, 210B and the third pillar 310 may be the same.

According to some example embodiments, the first via 120 may be disposed between the first pillar 110 and the package substrate 50. The first via 120 may be disposed on the first pillar 110. Specifically, the first via 120 may be disposed on the first pillar front side surface 110FS of the first pillar 110. The first via 120 may be electrically connected to the first pillar 110. The first via 120 may extend along the first direction X from the first pillar 110 toward the package substrate 50. The first via 120 may penetrate the molding layer 400. The first via 120 may be surrounded by the molding layer 400.

According to some example embodiments, the width of the first via 120 may not be constant. For example, the width of the first via 120 may decrease with distance from the package substrate 50. The width of a first via back side surface 120BS in contact with the first pillar 110 may be smaller than the width W2 of a first via front side surface 120FS in contact with the package substrate 50. Meanwhile, the width W2 of the first via front side surface 120FS may be equal to or smaller than the width W1 of the first pillar back side surface 110BS.

According to some example embodiments, the first via 120 may contain multiple membranes. Specifically, the first via 120 may include a seed layer 121 and a filling layer 122. At least a portion of the seed layer 121 may contact the first pillar 110. At least a portion of the seed layer 121 may contact the molding layer 400. In terms of shape, the seed layer 121 may be formed to surround the filling layer 122, which may form a rod-shaped core. The rod-shaped core may be circular in shape or rectilinear in shape when viewed from above. However, the present disclosure is not limited thereto. The seed layer 121 may extend corresponding to the filling layer 122 extending along the first direction X. Based on a method of manufacturing the first via 120, the filling layer 122 may be disposed on the seed layer 121. The filling layer 122 may be disposed in the space on the seed layer 121. The filling layer 122 may fill the space on the seed layer 121. The filling layer 122 may include copper (Cu). However, the present disclosure is not limited thereto. For example, the filling layer 122 may include metal materials such as titanium (Ti), aluminum (Al), silver (Ag), tin (Sn), gold (Au), nickel (Ni), or lead (Pb), or alloys thereof.

According to some example embodiments, the seed layer 121 may include a first seed layer 121a and a second seed layer 121b. At least a portion of the first seed layer 121a may be in direct contact with the first pillar 110. The first seed layer 121a may include titanium (Ti). However, the present disclosure is not limited thereto. For example, the first seed layer 121a may contain metal materials such as copper (Cu), aluminum (Al), silver (Ag), tin (Sn), gold (Au), nickel (Ni), lead (Pb), or alloys thereof.

According to some example embodiments, based on a method of manufacturing the first via 120, the second seed layer 121b may be disposed on the first seed layer 121a. The second seed layer 121b may be disposed between the first seed layer 121a and the filling layer 122. In terms of shape, the second seed layer 121b may surround the filling layer 122, which may form a rod-shaped core, and the first seed layer 121a may surround the second seed layer 121b. The second seed layer 121b may be extended according to the profile of the first seed layer 121a. The second seed layer 121b may include copper (Cu). However, the present disclosure is not limited thereto. For example, the second seed layer 121b may contain a metal material such as titanium (Ti), aluminum (Al), silver (Ag), tin (Sn), gold (Au), nickel (Ni), or lead (Pb), or alloys thereof.

According to some example embodiments, the surface roughness of the first via 120 may be greater than that of the first pillar 110. For example, the side of the first via 120 in contact with the molding layer 400 may be rougher than the side of the first pillar 110 in contact with the molding layer 400. The side of the first via 120 may be rougher than the side of the first pillar 110.

According to some example embodiments, the second via 220 may be disposed between the second pillar 210: 210A, 210B and the package substrate 50. The second via 220: 220A, 220B may be disposed on the second pillar 210: 210A, 210B. For example, the second via 220A may be disposed on the second pillar 210A, and the second via 220B may be disposed on the second pillar 210B. Specifically, the second via 220: 220A, 220B may be disposed on the front side surface of the second pillar 210: 210A, 210B. The second via 220: 220A, 220B may be electrically connected to the second pillar 210: 210A, 210B. The second via 220: 220A, 220B may extend along the first direction X from the second pillar 210: 210A, 210B toward the package substrate 50. The second via 220: 220A, 220B may penetrate the molding layer 400. The second via 220: 220A, 220B may be surrounded by the molding layer 400.

According to some example embodiments, the length of the second via 220 may vary depending on the distance between the plurality of second chips 200: 200A, 200B and the package substrate 50 in the first direction X. For example, the length of the second via 220 disposed between the second chip 200 disposed closer to the first chip 100 than the third chip 300 and the package substrate 50 may be greater than the length of the second via 220 disposed between the package substrate 50 and another second chip 200 disposed closer to the third chip 300 than the first chip 100.

According to some example embodiments, the width of the second via 220: 220A, 220B may not be constant. For example, the width of the second via 220: 220A, 220B may decrease with distance from the package substrate 50. Description of the second via 220: 220A, 220B may be substantially the same as the description of the first via 120, so the description of the second via 220 may be omitted.

According to some example embodiments, the molding layer 400 may be disposed on the package substrate 50. The molding layer 400 may cover a back side surface 50BS of the package substrate. The molding layer 400 may cover the first chip 100, the second chip 200: 200A, 200B, and the third chip 300 on the package substrate 50. The molding layer 400 may surround the first chip 100, the second chip 200: 200A, 200B, and the third chip 300. The molding layer 400 may surround the first pillar 110, the second pillar 210: 210A, 210B, the third pillar 310, the first via 120, and the second via 220: 220A, 220B.

According to some example embodiments, the molding layer 400 may include an insulating material. In an example embodiment, the molding layer 400 may include an insulating polymer material such as epoxy molding compound (EMC). In another example embodiment, the molding layer 400 may include a thermosetting resin such as epoxy resin or a thermoplastic resin such as polyimide.

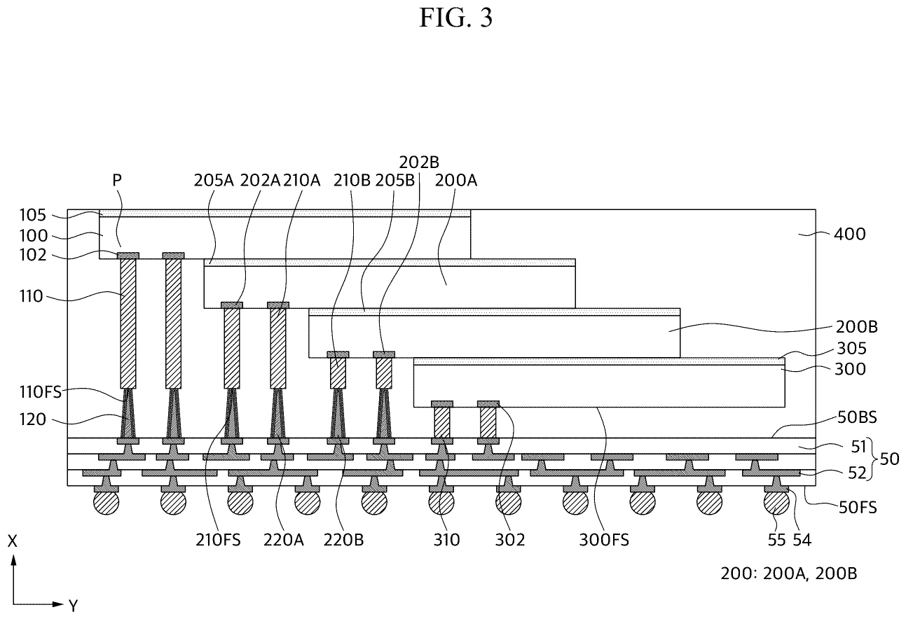

FIG. 3 is a diagram for explaining a semiconductor package according to an example embodiment. For convenience of explanation, differences from those described with reference to FIGS. 1 and 2 will be mainly described.

Referring to FIG. 3, the first pillar front side surface 110FS and a second pillar front side surface 210FS may be disposed on the same plane. For example, in the first direction X, the height of the first pillar front side surface 110FS and the height of the second pillar front side surface 210FS may be the same based on the back side surface 50BS of the package substrate.

According to some example embodiments, the height of the first via 120 and the second via 220: 220A, 220B may be the same. In the first direction X, the height of the first via 120 and the height of the second via 220: 220A, 220B may be the same based on the back side surface 50BS of the package substrate. Since the heights of the first via 120 and the second via 220: 220A, 220B may be the same, the process of forming the first via 120 and the second via 220: 220A, 220B may be simplified.

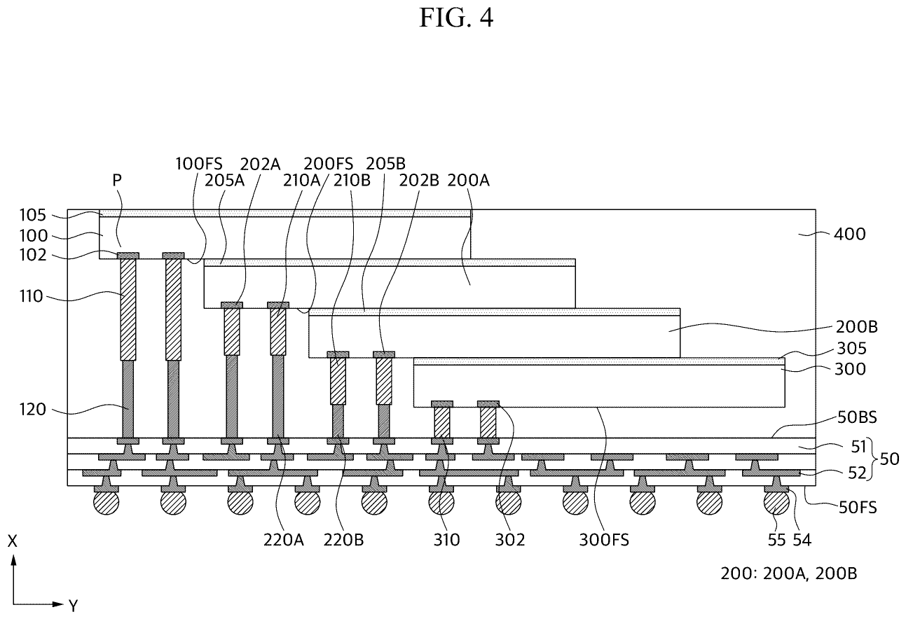

FIG. 4 is a diagram for explaining a semiconductor package according to an example embodiment. For convenience of explanation, differences from those described with reference to FIGS. 1 and 2 will be mainly described.

Referring to FIG. 4, the width of the first via 120 and the second via 220: 220A, 220B may be substantially constant, for example, within manufacturing tolerances. For example, as the first via 120 and the second via 220: 220A, 220B are distanced farther from the package substrate 50 in the first direction X, the width of the first via 120 and the width of the second via 220 in the second direction Y may be substantially constant. The width of the first via 120 and the width of the second via 220: 220A, 220B may be smaller than the width of the first pillar 110 and the width of the second pillar 210: 210A, 210B.

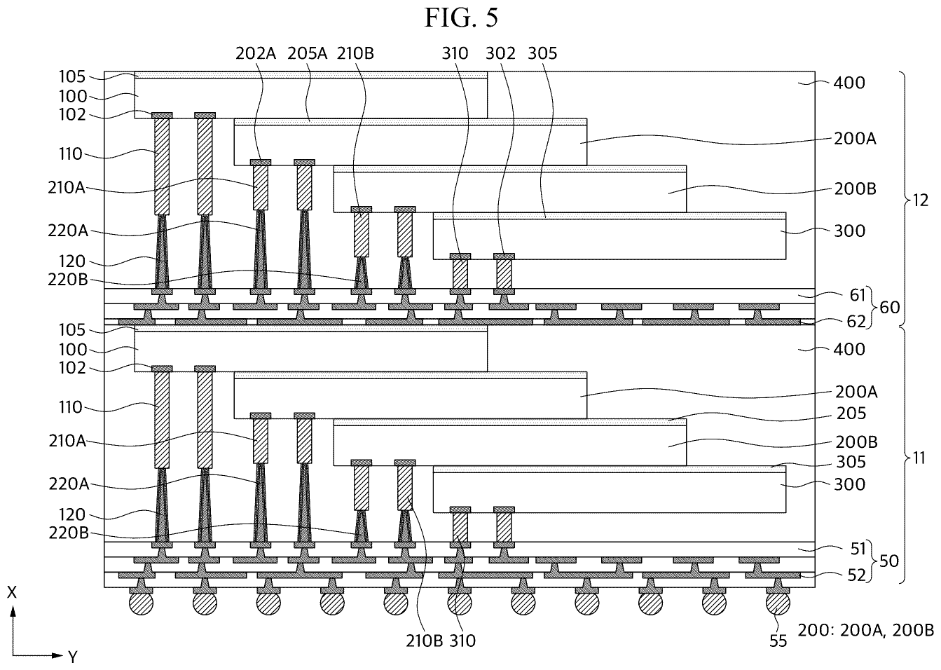

FIG. 5 is a diagram for explaining a semiconductor package according to an example embodiment. For convenience of explanation, differences from those described with reference to FIGS. 1 and 2 will be mainly described.

Referring to FIG. 5, a semiconductor package according to another embodiment may have a POP structure. A first package 11 and a second package 12 may be stacked in the first direction X to form a POP structure. The first package 11 may include the package substrate 50 (hereinafter referred to as the first package substrate 50 in the description of FIG. 5), and the second package 12 may include a second package substrate 60. Descriptions of the first pillar 110, the second pillar 210: 210A, 210B, the third pillar 310, the first via 120 and the second via 220: 220A, 220B may be applied to the first package 11 and the second package 12. Thus, repetitive descriptions may be omitted or simplified.

A wiring structure may electrically connect the first package substrate 50 and the second package substrate 60. For example, a pillar-shaped wiring structure may connect the first substrate wiring structure 52 of the first package substrate 50 and a second substrate wiring structure 62 of the second package substrate 60.

According to some example embodiments, the semiconductor package may be highly integrated by stacking the first package 11 and the second package 12. Meanwhile, since the first via 120 may be located on the first pillar 110 and the second via 220 may be located on the second pillar 210, the extending lengths of the first pillar 110, the second pillar 210, the first via 120, and the second via 220 in the first direction X may be relatively reduced. Therefore, the stability of the process for forming the first pillar 110, the second pillar 210, the first via 120, and the second via 220 may be improved.

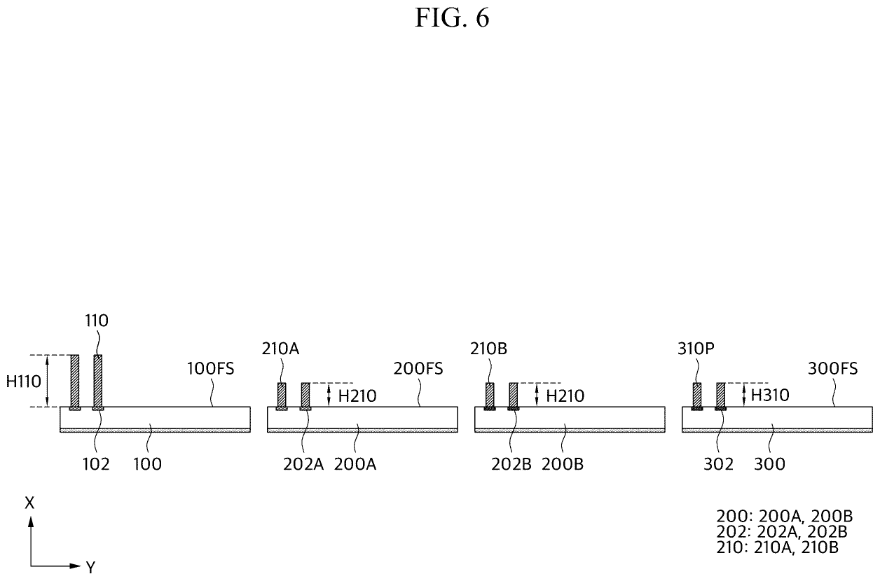

FIGS. 6 to 12 are diagrams illustrating intermediate processes for explaining a method for manufacturing a semiconductor package according to an example embodiment. For convenience of explanation, differences from those described with reference to FIGS. 1 and 2 will be mainly described. For reference, FIGS. 6 to 12 show a method of manufacturing the semiconductor package shown in FIG. 1.

Referring to FIG. 6, the first chip 100, the second chip 200: 200A, 200B and the third chip 300 may be formed. The first pillar 110, the second pillar 210: 210A, 210B and a third pre-pillar 310P may be located on the first chip 100, the second chip 200: 200A, 200B and the third chip 300, respectively. The first pillar 110 may be located on the first connection pad 102 exposed on the first chip front side surface 100FS. For example, the second pillar 210A may be located on the second connection pad 202A exposed on the second chip front side surface 200FS. The third pillar 310 may be located on the third connection pad 302 exposed on the third chip front side surface 300FS.

According to some example embodiments, the first pillar 110, the second pillar 210 and the third pre-pillar 310P may be located at the wafer level. In other words, the first pillar 110, the second pillar 210 and the third pre-pillar 310P may be located on the first chip 100, the second chip 200 and the third chip 300 in the fab-in state. The first pillar 110, the second pillar 210 and the third pre-pillar 310P may be formed together. Therefore, the first pillar 110, the second pillar 210 and the third pre-pillar 310P may contain the same constituent material. In other words, the materials forming the first pillar 110, the second pillar 210 and the third pre-pillar 310P may be the same. For example, each of the first pillar 110, the second pillar 210 and the third pre-pillar 310P may contain the same constituent material, and the composition ratio of each constituent material may be the same.

According to some example embodiments, in the first direction X, the height 110H of the first pillar 110 may be greater than the height H210 of the second pillar 210: 210A, 210B, and the height H310 of the third pre-pillar 310P. The height H210 of the second pillar 210: 210A, 210B and the height H310P of the third pre-pillar 310P may be the same or may be different.

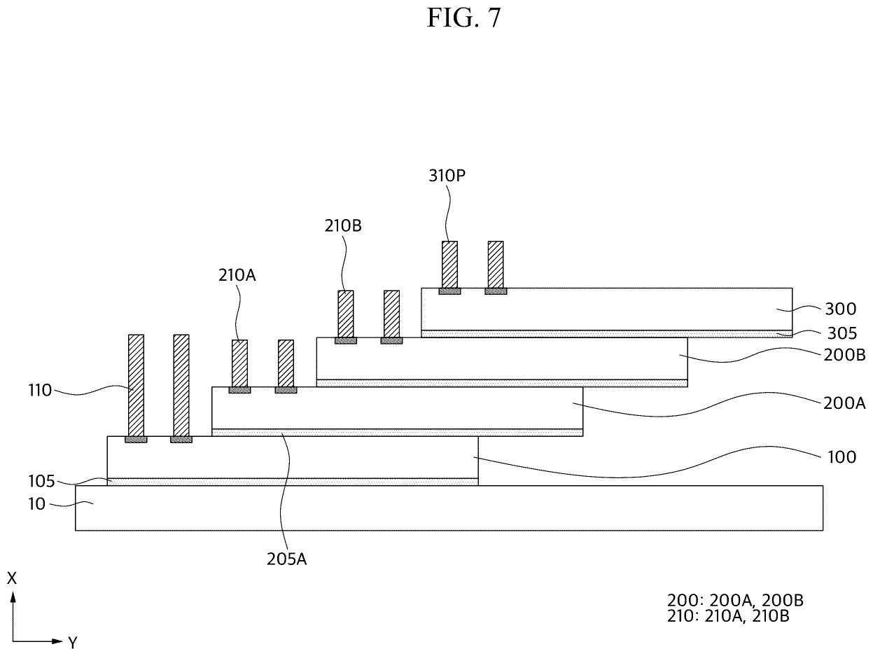

Further, referring to FIG. 7, the first chip 100, the second chip 200 and the third pre-pillar 310P may be stacked on a carrier substrate 10. The carrier substrate 10 may be an insulating substrate containing glass or polymer, or a conductive substrate containing metal. The first chip 100 may be attached to the carrier substrate 10 through the first adhesive layer 105. There may be the single second chips or a plurality of second chips 200: 200A, 200B, and the second chip 200 may be attached to the first chip 100 or another second chip (e.g., second chip 200B) through the second adhesive layer 205: 205A, 205B. The third chip 300 may be attached to the second chip 200 through the third adhesive layer 305.

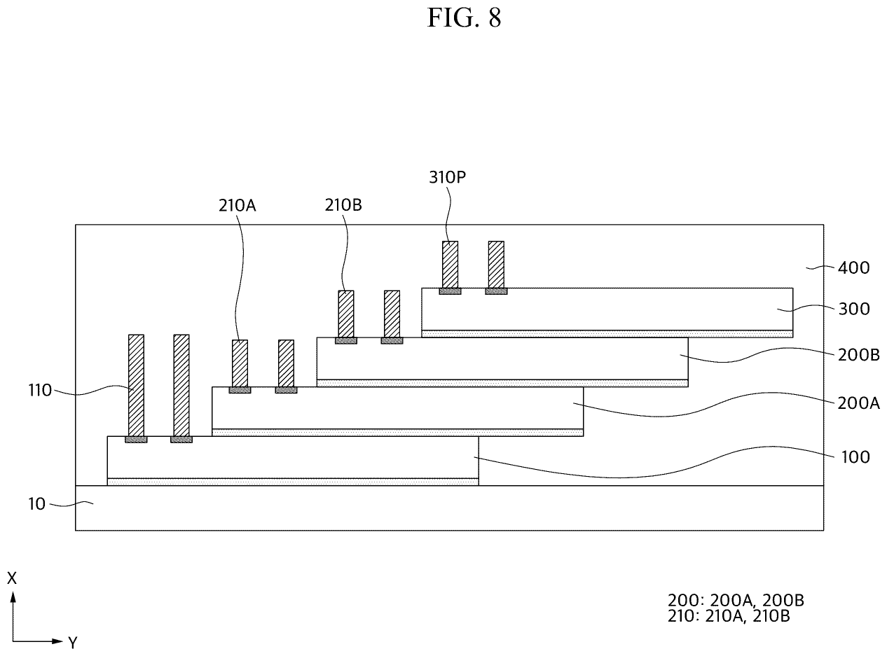

Further, referring to FIG. 8, a pre-molding layer 400P may be formed. The pre-molding layer 400P may cover the first chip 100, the second chip 200 and the third chip 300 disposed on the carrier substrate 10. The pre-molding layer 400P may surround the first pillar 110, the second pillar 210 and the third pillar 310. For example, the pre-molding layer 400P may cover upper surfaces of the first pillar 110, the second pillar 210 and the third pillar 310.

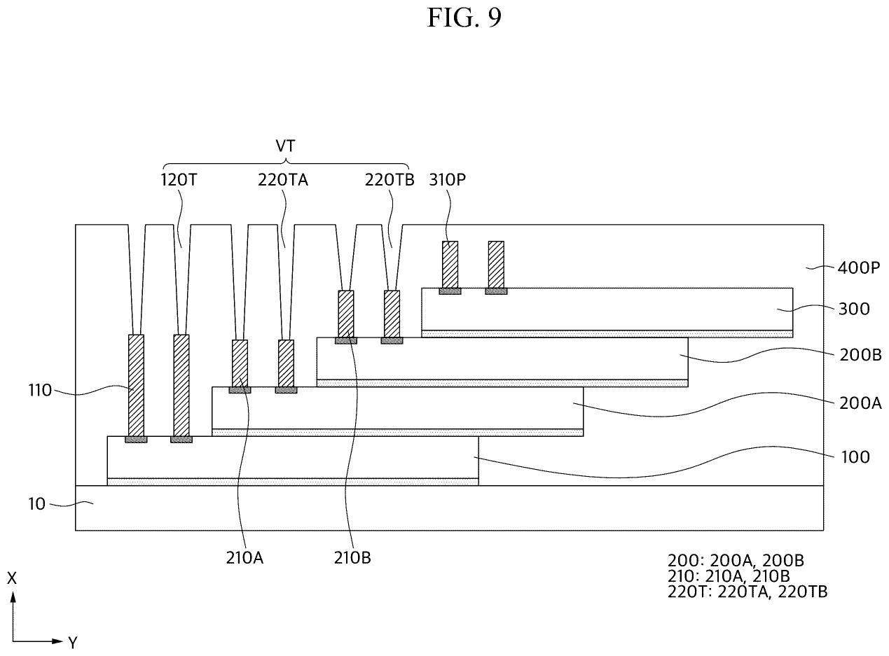

Further, referring to FIG. 9, a via trench VT may be formed. Specifically, a portion of the pre-molding layer 400P may be removed to form a first via trench 120T and a second via trench 220T. The first pillar 110 may be exposed through the first via trench 120T. The second pillar 210: 210A, 210B may be exposed through the second via trench 220T: 220TA, 220TB. For example, the second pillar 210A may be exposed through the second via trench 220TA, and the second pillar 210B may be exposed through the second via trench 220TB.

According to some example embodiments, the via trench VT may not be located on the third pillar 310. The third pillar 310 may be covered by the pre-molding layer 400P.

According to some example embodiments, the via trench VT may be formed using a laser. For example, a portion of the pre-molding layer 400P may be removed using a laser to form the via trench VT. The via trench VT may be circular in shape or rectilinear in shape when viewed from above. However, the present disclosure is not limited thereto. The via trench VT may penetrate the pre-molding layer 400P. Here, a surface of the inner wall of the via trench VT may be rough. As the pre-molding layer 400P containing fine particles may be removed, the surface of the inner wall of the via trench VT may be uneven.

According to some example embodiments, with the first pillar 110 and the second pillar 210 formed, in order to expose the first pillar 110 and the second pillar 210, the height of the via trench VT penetrating the pre-molding layer 400P may be reduced. Therefore, the process of forming the via trench VT may be simplified, and the first pillar 110 and the second pillar 210 may be stably exposed through the via trench VT.

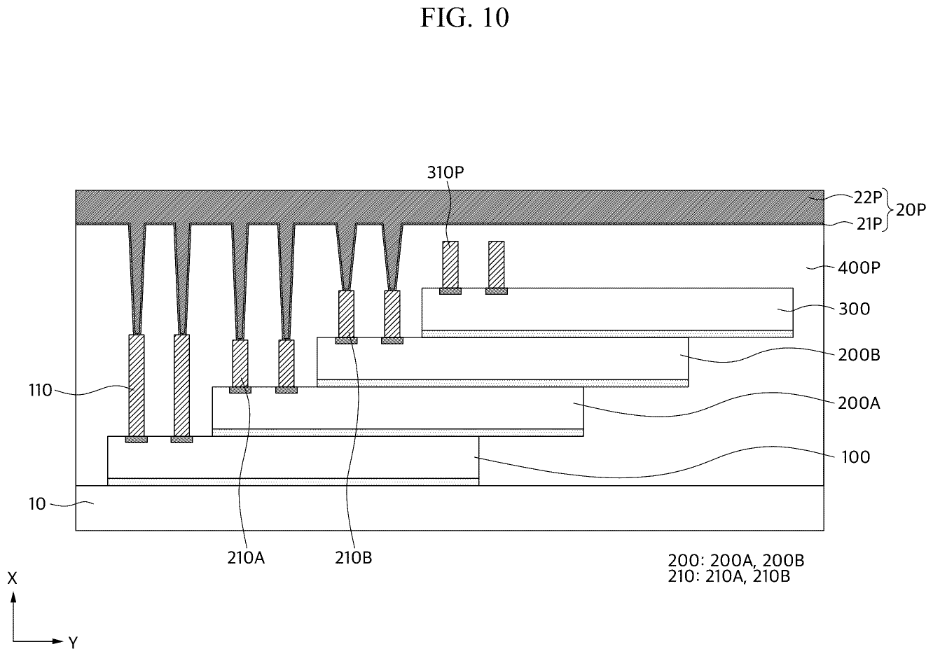

Further, referring to FIG. 10, a pre-via 20P may be formed. Specifically, a pre-seed layer 21P and a pre-filling layer 22P may be disposed in the via trench VT in FIG. 9. The, a pre-seed layer 21P and a pre-filling layer 22P may fill the via trench VT. The pre-seed layer 21P may extend along the profile of the via trench VT in FIG. 9 and the pre-molding layer 400P. The pre-filling layer 22P may be located on the pre-seed layer 21P. The pre-filling layer 22P may fill the via trench VT in FIG. 9 on the pre-seed layer 21P.

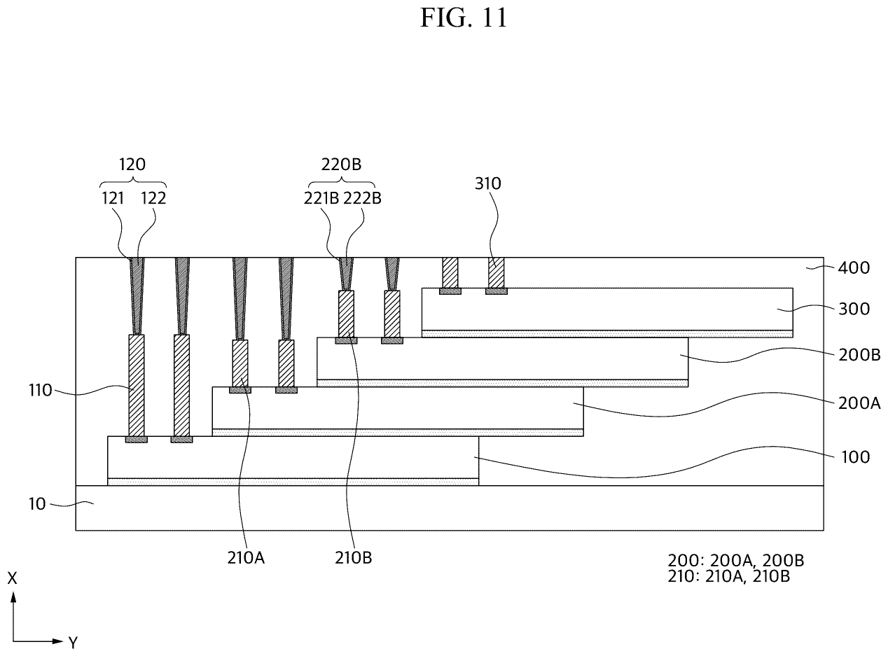

Further, referring to FIG. 11, the first via 120, the second via 220 and the third pillar 310 may be formed. Specifically, a portion of the pre-molding layer 400P in FIG. 10 may be removed to expose the third pillar 310. In the process of partially removing the pre-molding layer 400P in FIG. 10, the third pre-pillar 310P may also be partially removed. Therefore, in the first direction X, the height of the third pillar 310 may be less than the height of the second pillar 210.

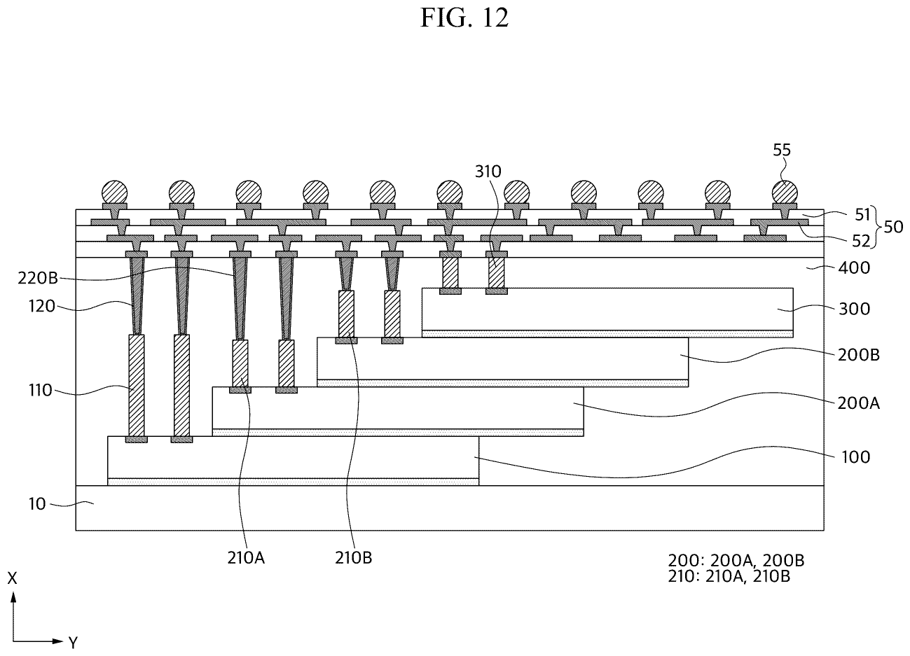

Further, referring to FIG. 12, the package substrate 50 may be located on the first via 120, the second via 220 and the third pillar 310. The substrate wiring structure 52 of the package substrate 50 may electrically connect the first via 120, the second via 220, and the third pillar 310.

Further, referring to FIG. 1, the carrier substrate 10 may be removed.

According to some example embodiments, in a case that the first pillar 110 may be connected to the substrate wiring structure 52 through the first via 120, the height of the first pillar 110 in the first direction X may be relatively reduced as compared to the case where the substrate wiring structure 52 extends to a surface of the molding layer 400. Therefore, in the process of forming the first pillar 110 extending in the first direction X, the risk of the first pillar 110 being bent in the second direction Y may be reduced.

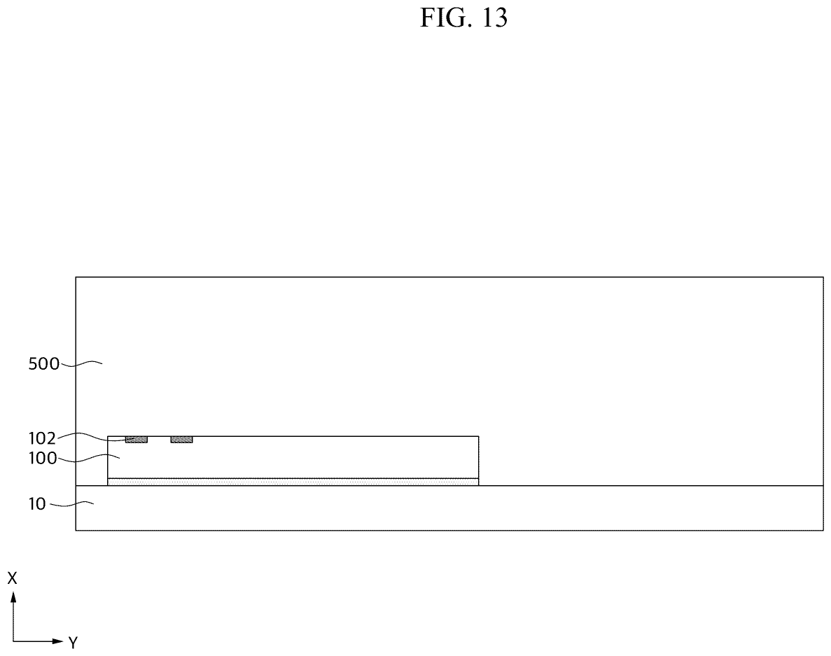

FIGS. 13 to 16 are diagrams illustrating intermediate processes for explaining a method of manufacturing a semiconductor package according to an example embodiment. For convenience of explanation, differences from those described with reference to FIGS. 6 to 12 will be mainly explained. For reference, FIGS. 13 to 16 are diagrams for explaining a method of forming the first pillar 110.

Referring to FIG. 13, a sacrificial insulating layer 500 covering the first chip 100 may be located on the carrier substrate 10. The sacrificial insulating layer 500 may include, for example, a photosensitive film or photoresist material.

According to some example embodiments, the first chip 100 may be fab out and disposed on the carrier substrate 10.

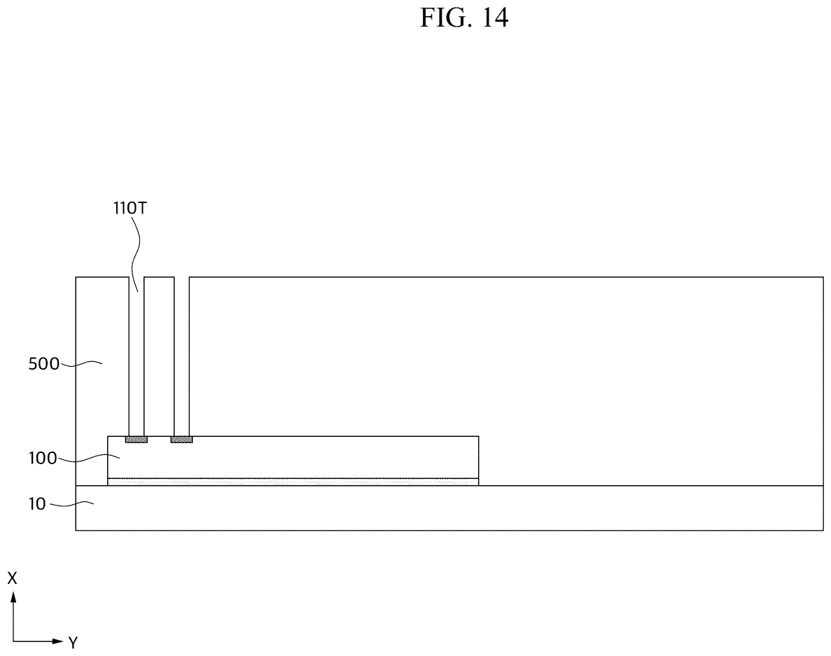

Further, referring to FIG. 14, a first pillar trench 110T may be formed. Specifically, a portion of the sacrificial insulating layer 500 may be removed to form the first pillar trench 110T. For example, the first pillar trench 110T may be formed through an exposure process. The first pillar trench 110T may penetrate the sacrificial insulating layer 500. The first connection pad 102 may be exposed through the first pillar trench 110T.

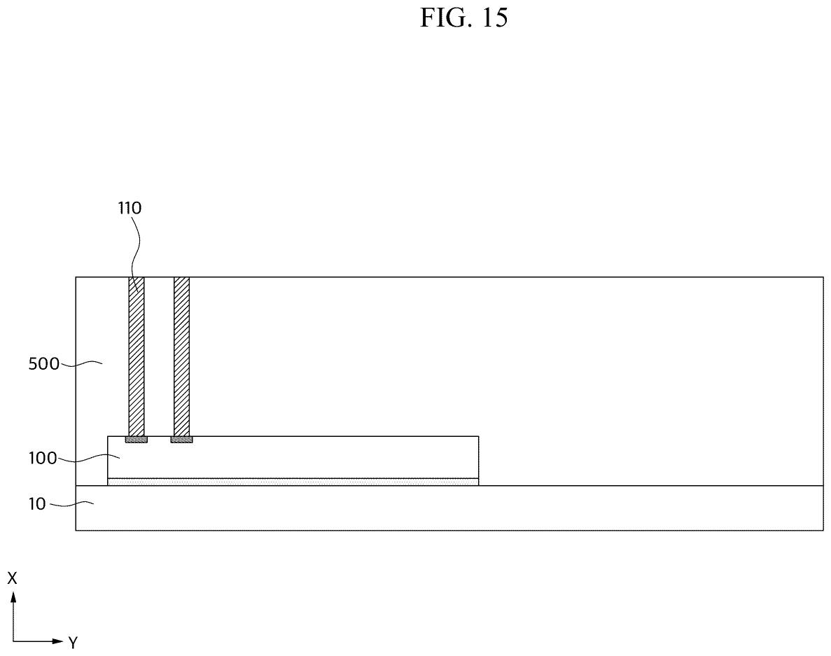

Further, referring to FIG. 15, the first pillar 110 may be formed. The first pillar 110 may be disposed in the first pillar trench 110T in FIG. 14. The first pillar 110 may fill the first pillar trench 110T.

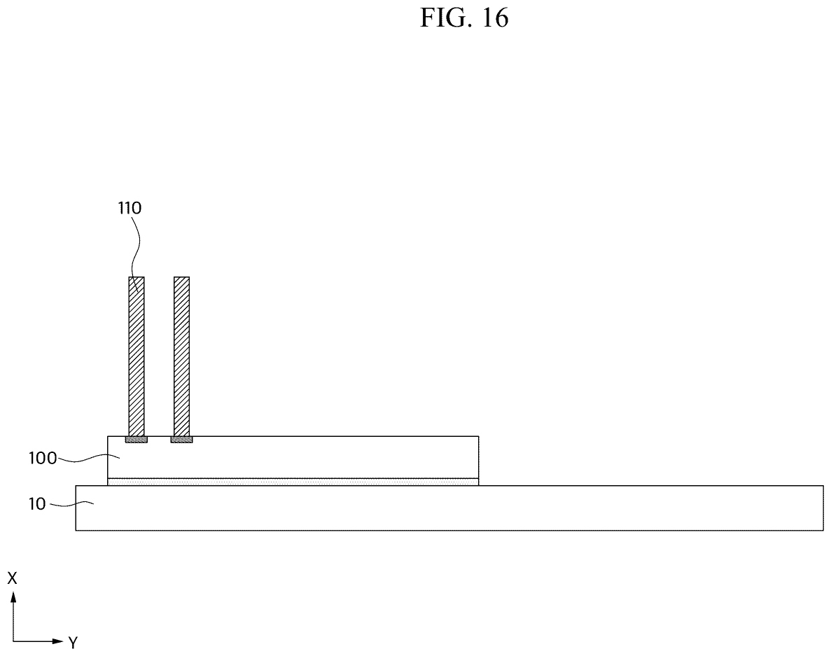

Further, referring to FIG. 16, the sacrificial insulating layer 500 in FIG. 15 may be removed.

Referring to FIG. 15 comparing to FIG. 16, when forming the first pillar 110 on the first chip 100 disposed on the carrier substrate 10, the height of the first pillar 110 may be large. When placing the first chip 100 on which the first pillar 110 is located on the carrier substrate 10 by picking and placing the first chip 100, if the height of the first pillar 110 in the first direction X is large, there is a risk of damage to the first pillar 110. Therefore, when the first pillar 110 is formed with the first chip 100 disposed on the carrier substrate 10, the height of the first pillar 110 may be made relatively large.

According to some example embodiments, the second pillar 210: 210A, 210B in FIG. 6 and the third pillar 310 in FIG. 6 may be formed in the fab-in state. Therefore, the first pillar 110 may have a different composition ratio from the second pillar 210: 210A, 210B in FIG. 6 and the third pillar 310 in FIG. 6. For example, even though the first pillar 110, the second pillar 210: 210A, 210B in FIG. 6 and the third pillar 310 in FIG. 6 all contain copper (Cu), the copper composition ratio of the first pillar 110 may be different from the copper (Cu) composition ratio of the second pillar 210: 210A, 210B in FIG. 6 and the third pillar 310 in FIG. 6.

Embodiments of the present disclosure are described in detail. However, it will be apparent to those with average knowledge in the technical field that scope of rights of this disclosure is not limited thereto, and various modifications and variations are possible without departing from the technical spirit of the present disclosure as set forth in the claims. Further, example embodiments may be implemented with some elements deleted, and example embodiments may be implemented in combination with each other.

What is claimed is:

1. A semiconductor package comprising:
a package substrate;
a first chip arranged to be spaced apart from the package substrate in a first direction perpendicular to the package substrate;
a second chip disposed closer to the package substrate than the first chip and spaced apart from the package substrate;
a first pillar extending along the first direction from the first chip toward the package substrate;
a first via disposed between the first pillar and the package substrate;
a second pillar extending along the first direction from the second chip toward the package substrate; and
a second via disposed between the second pillar and the package substrate,
wherein the first via and the second via have a width that decreases with distance away from the package substrate.

2. The semiconductor package of claim 1, wherein the first via has a surface that is rougher than a surface of the first pillar.

3. The semiconductor package of claim 1, wherein the first chip comprises:
an active surface that faces the package substrate; and
a first connection pad disposed on the active surface that is in contact with the first pillar.

4. The semiconductor package of claim 1, wherein each of the first via and the second via comprises:
a filling layer; and
a seed layer that surrounds the filling layer.

5. The semiconductor package of claim 4, wherein the seed layer comprises:
a first seed layer that is in contact with each of the first pillar and the second pillar; and
a second seed layer that is disposed between the first seed layer and the filling layer.

6. The semiconductor package of claim 5, wherein the first seed layer contains titanium, and the second seed layer contains copper.

7. The semiconductor package of claim 1, further comprising:
a third chip placed closest to the package substrate in the first direction; and
a third pillar extending along the first direction from the third chip to the package substrate,
wherein the first pillar contains a material that has same composition ratio as a material included in the second pillar and the third pillar.

8. The semiconductor package of claim 1, wherein the first pillar comprises a first pillar back side surface that is in contact with the first chip,
wherein the first via comprises a first via front side surface that is in contact with the package substrate, and
in a second direction intersecting the first direction, a width of the first via front side surface is identical to or smaller than a width of the first pillar back side surface.

9. The semiconductor package of claim 1, wherein the first pillar has a length that is longer than a length of the second pillar in the first direction.

10. The semiconductor package of claim 1, further comprising:
a third chip placed closest to the package substrate in the first direction; and
a third pillar extending along the first direction from the third chip to the package substrate,
wherein the third pillar has a length that is shorter than a length of the second pillar in the first direction.

11. The semiconductor package of claim 1, wherein a plurality of second chips are disposed between the first ship and the package substrate.

12. The semiconductor package of claim 1, further comprising:
a third chip placed closest to the package substrate in the first direction; and
a third pillar extending along the first direction from the third chip to the package substrate,
wherein an offset distance between the first chip and the second chip is identical to an offset distance between the second chip and the third chip in a second direction intersecting the first direction.

13. The semiconductor package of claim 1, wherein the first pillar comprises a first pillar front side surface facing the package substrate,
wherein the second pillar comprises a second pillar front side surface facing the package substrate, and
wherein the first pillar front side surface and the second pillar front side surface are disposed at an identical level above the package substrate.

14. A semiconductor package comprising:
a package substrate;
a first chip arranged to be spaced apart from the package substrate in a first direction perpendicular to the package substrate;
a second chip disposed closer to the package substrate than the first chip;
a third chip disposed closest to the package substrate in the first direction and spaced apart from the package substrate;
a first pillar extending along the first direction from the first chip toward the package substrate;
a first via disposed between the first pillar and the package substrate;
a second pillar extending along the first direction from the second chip toward the package substrate;
a second via disposed between the second pillar and the package substrate; and
a third pillar extending along the first direction from the third chip to the package substrate,
wherein the first via has a surface that is rougher than a surface of the first pillar, and
wherein the third pillar has a surface that is less rough than a surface of the first via.

15. The semiconductor package of claim 14, wherein each of the first via and the second via comprises a multilayer film.

16. The semiconductor package of claim 15, wherein each of the first via and the second via comprises:
a filling layer; and
a seed layer that surrounds the filling layer.

17. The semiconductor package of claim 14, wherein the first pillar has a length that is longer than a length of the second pillar in the first direction.

18. The semiconductor package of claim 14, wherein a portion of the first chip is offset from the second chip in the first direction, and comprises a first connection pad that is in contact with the first pillar, and
wherein a portion of the second chip is offset from the third chip in the first direction, and comprises a second connection pad that is in contact with the second pillar.

19. The semiconductor package of claim 14, wherein the first pillar comprises a first pillar back side surface that is in contact with the first chip,
wherein the first via comprises a first via front side surface that is in contact with the package substrate, and
wherein the first via front side surface has a width that is identical to or smaller than a width of the first pillar back side surface in a second direction intersecting the first direction.

20. A semiconductor package comprising:
a package substrate;
a first chip arranged to be spaced apart from the package substrate in a first direction perpendicular to the package substrate;
a second chip disposed closer to the package substrate than the first chip;
a third chip disposed closest to the package substrate in the first direction;
a first pillar extending along the first direction from the first chip toward the package substrate;
a first via disposed between the first pillar and the package substrate;
a second pillar extending along the first direction from the second chip toward the package substrate;
a second via disposed between the second pillar and the package substrate; and
a third pillar extending along the first direction from the third chip to the package substrate,
wherein the first via has a surface that is rougher than a surface of the first pillar, and
wherein the second via has a surface that is rougher than a surface of the second pillar.
